(19) United States
(12) Patent Application Publication
(10) Pub. No.: US 2024/0258990 A1
(43) Pub. Date: Aug. 1, 2024

(54) PIEZOELECTRIC VIBRATION DEVICE

(71) Applicant: DAISHINKU CORPORATION, Kakogawa-shi, Hyogo (JP)

(72) Inventor: Hiroki OKAMAE, Kakogawa-shi, Hyogo (JP)

(21) Appl. No.: 18/291,794

(22) PCT Filed: Sep. 13, 2022
(86) PCT No.: PCT/JP2022/034164

§ 371 Date: Jan. 24, 2024

(30) Foreign Application Priority Data
Sep. 24, 2021 (JP) 2021-155160

(51) Int. Cl. H03H 9/10; H03H 9/05; H03H 9/215

(52) U.S. Cl. CPC H03H 9/1021; H03H 9/0552; H03H 9/215

(57) ABSTRACT

A piezoelectric vibration device is provided that includes a piezoelectric vibration piece and a housing in which the piezoelectric vibration piece is containable. The piezoelectric vibration device further has electrically conductive pads formed on a surface of the housing to which the piezoelectric vibration piece is mountable. The piezoelectric vibration piece is bonded to the electrically conductive pads using metal bumps. An outer surface of the cabinet opposite to the mounting surface is dented toward the mounting surface so as to form a space that overlaps with the electrically conductive pads in plan view.

### TECHNICAL FIELD

This disclosure relates to piezoelectric vibration devices, examples of which may include piezoelectric vibrators and piezoelectric oscillators.

### BACKGROUND ART

Piezoelectric vibrators, for example, piezoelectric vibrators shaped like a tuning fork, have been and are currently used as clock source in a broad range of electric devices including watches.

The patent literature 1 describes a piezoelectric oscillator using a tuning fork-type crystal vibrator. This piezoelectric oscillator is equipped with a tuning fork-type crystal vibration piece and is also equipped with a container in which a housing recess is formed. The crystal vibration piece has connection electrodes, and the container has, in the housing recess, electrodes for mounting purpose. The connection electrodes of the crystal vibration piece are bonded with metal bumps to the electrodes of the container.

### CITATION LIST

### Patent Literature

Patent literature 1: Patent No. 6390206

### SUMMARY OF THE INVENTION

### Technical Problems

In the patent literature 1, the tuning fork-type piezoelectric vibration piece is bonded with metal bumps to the electrodes of the container. This structure, as compared with bonding using electrically conductive resin adhesives, may afford higher electrical conductivity and may also achieve smaller bonding area, thus conducing to higher bonding stability and miniaturization.

Such a structure, however, may involve some disadvantages, for example, manufacturing variability that possibly leads to the risk of vibration energy leakage. In the tuning fork-type piezoelectric vibration piece, balance adjustment between paired vibration arm portions may be an important factor to be addressed in view of vibration properties. Any degree of imbalance between the arm portions may fail to attenuate the vibration energy in a joint with the container (supports), causing the vibration energy to leak out of the container through the metal bumps. In the case of such poor manufacturing accuracy, the vibration energy of the vibration arm portions may possibly leak out into the container, which may be referred to as audio leakage. The event of audio leakage may invite variability of electric properties when the vibration piece or vibrator is used as a piezoelectric vibration device and mounted to an external circuit board.

When the container loaded with the tuning fork-type piezoelectric vibration piece is mounted to an external circuit board, any stress transmitted from the circuit board may not be adequately weakened, unlike bonding using electrically conductive resin adhesives. The stress transmitted then may adversely act upon the meal bump-used joint, possibly leading to poor connection reliability.

To address these issues of the known art, this disclosure is directed to providing technical means that enable full control of possible vibration energy leakage and desirable reduction of any stress that possibly acts upon the device from outside.

### SOLUTIONS TO THE PROBLEMS

To this end, this disclosure provides the following technical features.

A piezoelectric vibration device disclosed herein is equipped with a piezoelectric vibration piece and a cabinet having a housing in which the piezoelectric vibration piece is containable. The piezoelectric vibration device is further equipped with an electrically conductive pad on a mounting surface of the housing to which the piezoelectric vibration device is mountable. The piezoelectric vibration piece is bondable with a metal bump to the electrically conductive pad.

An outer surface of the cabinet on the opposite side of the mounting surface is recessed toward the mounting surface to form a space in a region that overlaps with the electrically conductive pad in plan view.

As the piezoelectric vibration piece placed in the housing of the cabinet is vibrated, the vibration generated then is transmitted to the cabinet through the electrically conductive pad of the mounting surface bonded to the piezoelectric vibration piece with the metal bump. The outer surface of the cabinet on the opposite side of the mounting surface is recessed toward the mounting-surface side, which forms a space that prevents the vibration from transmitting to a region that overlaps with the electrically conductive pad in plan view. This space may block or reduce the vibration possibly transmitting to the electrically conductive pad, thus preventing further spread of the vibration energy leakage. Thus, the risk of vibration energy leakage may be successfully reduced.

Thus, a space is formed in a region that overlaps with the electrically conductive pad in plan view. When, for example, the piezoelectric vibration device is mounted to an external circuit board and any stress is transmitted from this circuit board to the cabinet, this space may successfully block or reduce the vibration possibly transmitting to the joint of the electrically conductive pad with the metal bump. This may achieve higher connection reliability at the joint.

In a preferred embodiment of the technology disclosed herein, the piezoelectric vibration piece is a piezoelectric vibration piece in the form of tuning fork.

This embodiment may effectively control the risk of vibration energy leakage from two vibration arm portions of the tuning fork-type piezoelectric vibration piece.

In an embodiment of the technology disclosed herein, the piezoelectric vibration device has an external terminal on an outer bottom surface of the cabinet, and the external terminal is formed in a region with no overlap with the electrically conductive pad in plan view.

According to this embodiment, the external terminal is formed in a region with no overlap in plan view with the electrically conductive pad joined to the piezoelectric vibration piece with the metal bump. This may prevent any vibration of the piezoelectric vibration piece from transmitting to the eternal terminal through the joint of the electrically conductive pad with the metal bump, thus reducing the likelihood of vibration energy leaking out of the cabinet.

In an embodiment of the technology disclosed herein, the cabinet has a base member and a lid member. The base member includes the external terminal and the mounting surface on which the electrically conductive pad is formed. The lid member is bonded to the base member to seal the housing. The base member further has a substrate portion, a first frame portion and a second frame portion. The first frame portion is formed in an annular manner in an outer periphery of one main surface of the substrate portion. The second frame portion is formed in an annular manner in an outer periphery of the other main surface of the substrate portion. The lid member is bonded to an upper end surface of the first frame portion. The housing is formed by the substrate portion, the first frame portion and the lid member. The external terminal is formed on a lower end surface of the second frame portion.

According to this embodiment, the lid member is bonded to the base member mounted with the piezoelectric vibration piece, so that the housing containing the piezoelectric vibration piece is hermetically sealable.

The piezoelectric vibration piece is placed in and sealed by the housing formed by the substrate portion, first frame portion and lid member, while electronic elements like sensors and IC are placed in a housing recess formed by the substrate portion and the second frame portion. Thus, the second frame portion disposed between the external terminal and the electrically conductive pad having the bump-bonded piezoelectric vibration piece may serve as a shock absorber against any external stress, avoiding possible property changes of the piezoelectric vibration piece.

In an embodiment of the technology disclosed herein, a region defined by an inner peripheral edge of the second frame portion on the other main surface of the substrate portion of the base member has a greater dimension in plan view than a region defined by an inner peripheral edge of the first frame portion on the one main surface of the substrate portion.

According to this embodiment, a region defined by an inner peripheral edge of the second frame portion on the substrate portion of the base member, i.e., space surrounded by the annular second frame portion, is dimensionally greater in plan view than a region defined by an inner peripheral edge of the first frame portion in the substrate portion of the base member (frame portion containing the piezoelectric vibration piece), i.e., space surrounded by the annular first frame portion. When the piezoelectric vibration piece on the side of the first frame portion is vibrated, the space on the side of the second frame portion, which is greater than the space on the side of the first frame portion, may successfully prevent any vibration generated then from transmitting toward the second frame portion where the external terminal is formed. Thus, any vibration generated then may be blocked not to transmit to the external terminal. As a result, further spread of the vibration to the external terminal may be effectively controlled, which may reduce the risk of vibration energy leakage.

In an embodiment of the technology disclosed herein, the substrate portion and the second frame portion form a housing recess in which an integrated circuit element is containable, the integrated circuit element is mounted to the other main surface of the substrate portion, and a region mounted with the integrated circuit element does not overlap in plan view with a region of joint of the electrically conductive pad with the metal bump.

The piezoelectric oscillator according to this embodiment may be so structured that the piezoelectric vibration piece is housed in the housing on the side of one main surface of the substrate portion, and the integrated circuit element is housed in the housing recess on the side of the other main surface of the substrate portion.

The region on the side of the other main surface of the substrate portion is mounted with the integrated circuit element, and this region does not overlap in plan view with the region of joint of the electrically conductive pad with the metal bump. Thus, any vibration generated from the piezoelectric vibration piece on the side of one main surface of the substrate portion may be prevented from transmitting, through the joint of the electrically conductive pad with the metal bump, toward the integrated circuit element on the side of the other main surface of the substrate portion. Thus, the risk of vibration energy leakage may be successfully reduced.

In an embodiment of the technology disclosed herein, the substrate portion and the second frame portion form a housing recess in which an integrated circuit element is containable, the integrated circuit element is mounted to the other main surface of the substrate portion, and a region mounted with the integrated circuit element is filled with an underfill that spreads as far as a region of joint of the electrically conductive pad with the metal bump in plan view.

According to this embodiment, the underfill applied to the region mounted with the integrated circuit spreads as far as the region of joint of the electrically conductive pad with the metal bump in plan view. Thus, the resin-made, elastically deformable underfill may effectively absorb any vibration generated from the region of joint of the metal bump with the electrically conductive pad of the base member made of a hard ceramic material.

In an embodiment of the technology disclosed herein, a stepped portion is formed on the one main surface of the substrate portion of the cabinet, the electrically conductive pad is formed on an upper surface of the stepped portion to constitute the mounting surface. Further, a first thickness is greater than a second thickness and the second thickness is greater than a third thickness, where the first thickness is a dimension from the mounting surface to the external terminal in a direction of thickness which is a direction orthogonal to the one main surface of the substrate portion of the cabinet, the second thickness is a dimension in the direction of thickness of a region where the electrically conductive pad is formed, and the third thickness is a dimension in the direction of thickness of the region mounted with the integrated circuit element.

According to this embodiment, the second thickness; thickness of the region of formation of the electrically conductive pad to which the piezoelectric vibration piece is bonded with the metal bump, differs from the first thickness; thickness from the external terminal to the mounting surface where the electrically conductive pad is formed, and also differs from the third thickness; thickness of the region mounted with the integrated circuit element. These differences in thickness may serve to weaken the vibration transmitted from the piezoelectric vibration piece through the joint of the electrically conductive pad with the metal bump, effectively reducing the risk of vibration energy leakage to the external terminal and the integrated circuit element.

### Effects of the Invention

The vibration of the piezoelectric vibration piece in the housing of the cabinet may be transmitted to the cabinet through the electrically conductive pad on the mounting surface bonded with the metal bump to the piezoelectric vibration piece. The outer surface of the cabinet on the opposite side of the mounting surface is recessed to form a space in a region that overlaps with the electrically conductive pad in plan view. This space may effectively block the vibration from the electrically conductive pad, serving to reduce the risk of further spread of vibration energy leakage.

When the piezoelectric vibration device may be mounted to an external circuit board, any stress generated from the circuit board may be imposed on the cabinet. In this instance, the space formed in the region that overlaps with the electrically conductive pad in plan view may reduce the risk of the stress being transmitted to the joint of the electrically conductive pad with the metal bump, conducing to higher connection reliability of the joint.

### BRIEF DESCRIPTION OF THE DRAWINGS

FIG. 1 is a schematic view in cross section of a crystal oscillator according to an embodiment of this disclosure.

FIG. 2 is a plan view of the crystal oscillator of FIG. 1 from which a lid member has been removed.

FIG. 3 is a drawing of a base member when viewed in cross section along A-A line of FIG. 2.

FIG. 4 is drawing of a tuning fork type crystal vibration piece when viewed from the side of one main surface.

FIG. 5 is drawing of the tuning fork-type crystal vibration piece when viewed from the side of the other main surface.

FIG. 6 is a schematic view in cross section of a crystal oscillator according to the known art.

FIG. 7 is a graph showing the result of frequency reproducibility according to the embodiment.

FIG. 8 s a graph showing the result of frequency reproducibility according to the known art.

FIG. 9 is a schematic view in cross section of a crystal oscillator according to an embodiment of this disclosure, illustrated correspondingly to FIG. 1.

FIG. 10 is a plan view of the crystal oscillator according to the embodiment of FIG. 9, illustrated correspondingly to FIG. 2.

FIG. 11 is a schematic view in cross section of the crystal oscillator according to an embodiment, illustrated correspondingly to FIG. 1.

### DESCRIPTION OF EMBODIMENTS

Embodiments of the technology disclosed herein are hereinafter described in detail with reference to the accompanying drawings.

This embodiment describes, as an example of piezoelectric vibration devices, a crystal oscillator including a crystal vibration piece of tuning fork type and IC; integrated circuit element. In this crystal oscillator, the crystal vibration piece and the IC are housed in one cabinet.

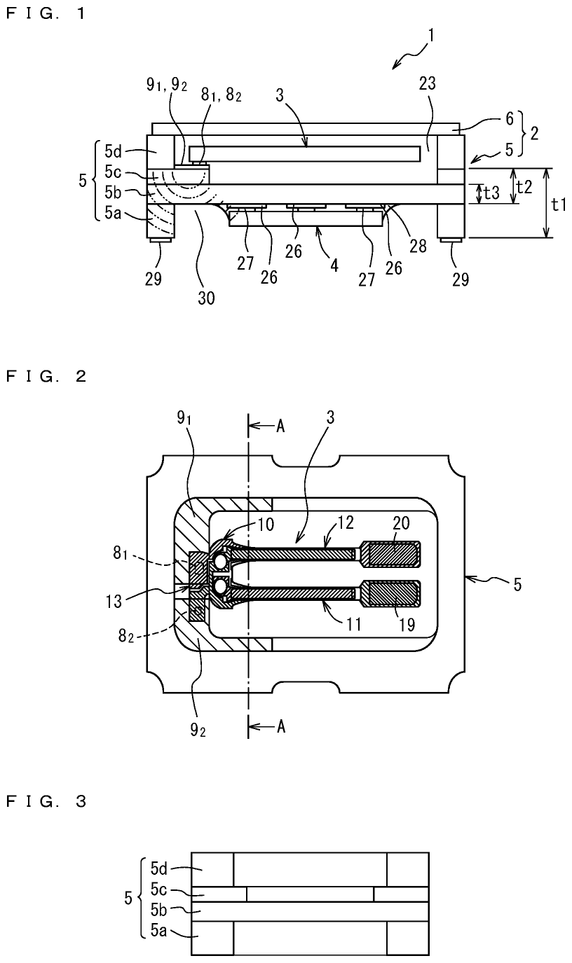

FIG. 1 is a schematic view in cross section of the crystal oscillator according to an embodiment of this disclosure. FIG. 2 is a plan view of the crystal oscillator of FIG. 1 from which a lid member 6 has been removed.

A crystal oscillator 1 described in this embodiment is equipped with a cabinet 2, a turning fork type crystal vibration piece 3, and an IC 4. The crystal vibration piece 3 is housed in the cabinet, and the IC 4 is mounted to the cabinet 2.

The cabinet 2 has a base member 5 as its main body and also has a lid member 6. The base member 5 is made of a ceramic material like alumina. The base member 5 is so structured that ceramic green sheets are stacked in layers. To be specific, multiple layers; a first layer 5a, a second layer 5b, a third layer 5c and a fourth layer 5d, are fired into an integral unit to form this base member.

The second layer 5b forms a substrate portion rectangular in plan view. The third layer 5c and the fourth layer 5b on this second layer 5b form a first frame portion on one of main surfaces of the substrate portion. The first frame portion has a rectangular shape and is formed in an annular manner. The third layer 5c below the first frame portion has, on one short side of the rectangular shape (left side on FIGS. 1 and 2), a portion protruding more inward than the fourth layer 5d. The third layer 5c has, on opposing long sides of the rectangular shape (upper and lower sides on FIG. 2), portions slightly protruding more inward than the fourth layer 5d. On the upper surface of the substrate portion is formed a stepped portion which is defined by the portion protruding inward from the one short side and portions protruding inward from the opposing long side.

A part of this stepped portion on the one short side is a mounting surface to be mounted with the tuning fork-type crystal vibration piece 3. On this mounting surface are formed a first electrically conductive pad 9₁ and a second electrically conductive pad 9₂. As illustrated in FIG. 2, the first electrically conductive pad 9₁ extends from one of the two opposing long sides (upper side on FIG. 2) toward a position closer to the other long side than the center in a direction along the short sides (vertical direction on FIG. 2). The second electrically conductive pad 9₂ extending from the other one of the opposing long sides (lower side on FIG. 2) in the direction along the short sides is shorter than the first electrically conductive pad 9₁. In the first and second electrically conductive pads 9₁ and 9₂, their ends in the direction along the short sides are extending toward positions on the other short side (right side on FIGS. 1 and 2).

The tuning fork type crystal vibration piece 3 is bonded to the first and second electrically conductive pads 9₁ and 9₂ with first and second metal bumps 8₁ and 8₂ described later. These electrically conductive pads 9₁ and 9₂ are connected, with an internal wiring, not shown, of the base member 5, to two of six electrode pads 26 formed on the lower surface of the second layer 5b that constitute the substrate portion, as described later.

The first layer 5a forms a second frame portion on one of the main surfaces of the substrate portion formed by the second layer 5b. The second frame portion has a rectangular shape and is formed in an annular manner.

The base member 5 has the substrate portion, the first frame portion and the second frame portion. The substrate portion includes the second layer 5b rectangular in plan view. The first frame portion has a rectangular shape and includes the rectangular third layer 5c and fourth layer 5d. The first frame portion is formed in an annular manner in the outer periphery of the substrate portion's upper surface. The second frame portion has a rectangular shape and includes the first layer 5a. The second frame portion is formed in an annular manner in the outer periphery of the substrate portion's lower surface. As illustrated in FIG. 1, the base member 5 has a shape like a substantially H-like package in cross section.

In the H-like package structure, the third layer 5c and the fourth layer 5d on the second layer 5b forming the substrate portion of the base member 5 serve as the rectangular first frame portion. The third layer 5c has, on the opposing long side of the rectangular shape (upper and lower sides on FIG. 2), portions slightly protruding more inward than the fourth layer 5d.

The third layer 5c is thus protruding inward from the opposing long sides. Two spaces are compared here; a space for housing of the IC4 which is defined by the substrate portion including the second layer 5b and the second frame portion including the first layer 5a below the second layer 5b, and a space for housing of the crystal vibration piece 3 which is defined by the substrate portion including the second layer 5b and the first frame portion including the third and fourth layers 5c and 5d. As illustrated in FIG. 3 showing the base member 5 in A-A cross section of FIG. 2, the space for housing of the IC4, because of no stepped portion protruding inward, is dimensionally greater than the space for housing of the crystal vibration piece 3.

Thus, a region defined by the inner peripheral edge of the second frame portion on one main surface of the substrate portion of the base member 5 in plan view; i.e., a region defined by the inner peripheral edge of the first layer 5a, is dimensionally greater than a region defined by the inner peripheral edge of the first frame portion on the other main surface of the substrate portion of the base member 5; i.e., a region defined by the inner peripheral edge of the third layer 5c.

The packaging material used then may include a glass material as its insulating material, instead of any ceramic material.

The lid member 6 is hermetically bonded, with a sealing member not shown, to the upper end surface of the fourth layer 5d of the base member 5. This forms a housing 23 in which the tuning fork-type crystal vibration piece 3 is containable. The base member 5 and the lid member 6 are bonded to each other in a vacuum atmosphere or in an inactive gas atmosphere using, for example, nitrogen gas. Examples of the material for the lid member 6 may include, for example, metals, ceramic materials and glass materials. The lid member 6 is formed, for example, in a plate-like shape rectangular in plan view.

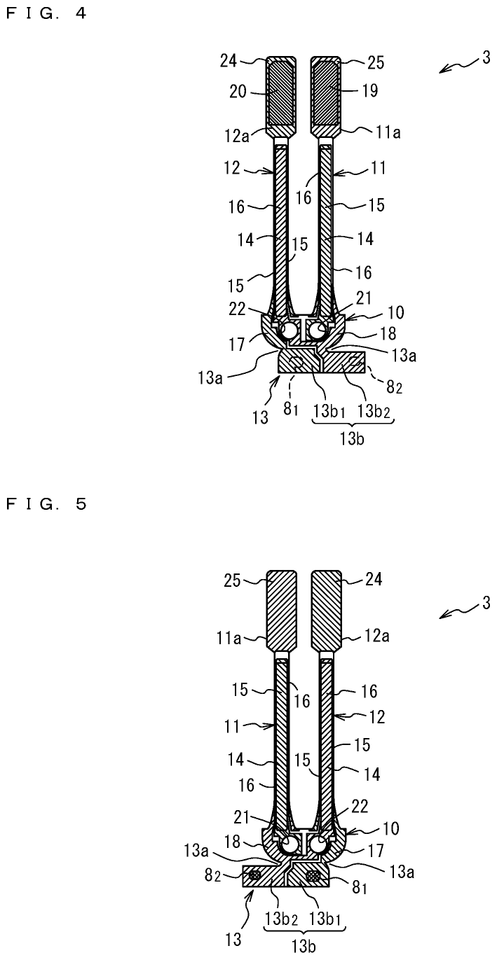

FIG. 4 is an enlarged plan view from one main surface side of the tuning fork-type crystal vibration piece 3 housed in the housing 23 of the cabinet 2. FIG. 5 is an enlarged plan view from the other main surface side of the tuning fork-type crystal vibration piece 3 housed in the housing 23 of the cabinet 2.

As illustrated in FIGS. 4 and 5, the tuning fork type crystal vibration piece 3 has a base portion 10, a pair of first and second arm portions 11 and 12, and a joint portion 13. The base portion 10 has a laterally symmetric shape in plan view. The first and second arm portions 11 and 12 are paired vibration arms extending in parallel from the side of one end surface of the base portion 10. The joint portion 13 is formed on one end side of the base portion 10 to be joined to the base member 5.

This joint portion 13 has an extension 13b. The extension 13b is continuous through a constricted part 13a smaller in width than the base portion 10. The joint portion 13 is allowed to attenuate, by using this constricted part 13a, any vibration transmitted from the first and second arm portions 11 and 12. The extension 13b has a protruding part 13b1 and a bent part 13b2. The protruding part 13b1 protrudes from the base portion 10 in a direction opposite to the first and second arm portions 11 and 12. The bent part 13b2 bends from the protruding part 13b1 in a direction orthogonal to the direction of extension of the first and second arms portions 11 and 12.

In the extension 13b thus bending in the direction orthogonal to the direction of extension of the first and second arm portions 11 and 12, its bent part may serve well to attenuate any vibration transmitted from the first and second arm portions 11 and 12, successfully reducing the risk of vibration energy leakage.

A first metal bump 8₁ is formed at the protruding part 13b1 that protrudes opposite to the first and second arm portions 11 and 12. A second bump 8₂ is formed at the bent part 13b2 bending orthogonal to the direction of extension of the first and second arm portions 11 and 12. The first metal bump 8₁ at the protruding part 13b1 protruding from the base portion 10 opposite to the first and second arm portions 11 and 12 is disposed at substantially the center in a direction of width of the base portion 10 laterally symmetric in plan view. The first metal bump 8₁ of the protruding part 13b1 is thus disposed at substantially the center in the direction of width of the base portion 10; the origin of extension of the first and second arm portions 11 and 12 of the tuning fork-type crystal vibration piece 3. Thus, the vibration energy of the first and second arm portions 11 and 12 of the tuning fork-type crystal vibration piece 3 may be mostly transmitted to the base member 5 through the first metal bump 8₁ of the protruding part 13b1. The first metal bump 8₁ is dimensionally greater in plan view than the second metal bump 8₂.

As illustrated in FIG. 2, the tuning fork-type crystal vibration piece 3 may be bonded, using the first metal bump 8₁ of the protruding part 13b1, to the first electrically conductive pad 9₁ at substantially the center in a direction along short sides of the base member 5 rectangular in plan view (vertical direction on FIG. 2).

The first metal bump 8₁ receives the vibration energy from substantially the center in the direction of width of the base portion 10 of the crystal vibration piece 3. This first metal bump 8₁ is thus located and bonded at substantially the center in the direction along short sides of the base member 5 rectangular in plan view (vertical direction on FIG. 2). Then, the vibration energy from the first, second arm portion 11, 12 of the crystal vibration piece 3 may be transmitted to the base member 5 in a well-balanced manner along short sides of the base member 5. Thus, the risk of vibration energy leakage may be controlled well, in comparison to the metal bump 8₁ of the base portion 10 being positioned in an unbalanced manner, for example, being positioned with a lean to one side along its short sides, in the crystal vibration piece 3.

In the paired first and second arm portions 11 and 12, their head parts 11a and 12a are formed in a larger dimension than the other portions in a direction orthogonal to the direction of extension of the arm portions, i.e., in a direction of width of the head parts (lateral direction on FIGS. 4 and 5).

The first and second arm portions 11 and 12 respectively have, on their main surfaces on both sides illustrated in FIGS. 4 and 5, grooves 14 that extend along the direction of extension of the arm portions 11 and 21.

The tuning fork-type crystal vibration piece 3 has two driving electrodes; first driving electrode 15 and second driving electrode 16, and also has extraction electrodes 17 and 18 extracted from the driving electrodes 15 and 16. The extraction electrodes 17 and 18 are used to electrically connect the driving electrodes 15 and 16 to the electrode pads 9₁ and 9₂ of the base member 5. These two first and second driving electrodes 15 and 16 are partly formed inside of the grooves 14 of the main surfaces.

The first driving electrode 15 is formed on the lateral surfaces and the main surfaces, including the grooves 14, of the first arm portion 11, and is all connected to the extraction electrode 17. Likewise, the second driving electrode 16 is formed on the lateral surfaces and the main surfaces, including the grooves 14, of the second arm portion 12, and is all connected to the extraction electrode 17.

Through electrodes 21 and 22 are formed in a pair in the region of the base portion 10 where the driving electrodes 15 and 16 are formed. The driving electrodes 15 and 16 on the main surfaces are connected through these electrodes 21 and 22.

Arm tip electrodes 25 and 24 are formed in all over the head parts 11a and 12a of the first and second arm portions 11 and 12. The arm tip electrode 25 formed in the whole head part 11a is connected to the second driving electrode 16 formed on the lateral surfaces of the first arm portion 11. The arm tip electrode 26 formed in the whole head part 12a is connected to the first driving electrode 15 formed on the lateral surfaces of the second arm portion 12.

Metal films 19 and 20 for frequency adjustment are formed on the arm tip electrodes 25 and 24 on the side of one main surface illustrated in FIG. 4 in a slightly smaller area(s) than these arm tip electrodes. The metal films 19 and 20 are reducible in mass by being irradiated with, for example, laser beam. In this manner, the frequency of the tuning fork-type crystal vibration piece 3 may be roughly adjustable.

The extraction electrode 17 extracted from the first driving electrode 15 is further extended at a position closer to the base portion 10 of the extension 13b of the joint portion 13. The extraction electrode 18 extracted from the second driving electrode 16 is further extended at a position closer to the end of extension of the extension 13b.

Two metal bumps 8₁ and 8₂, serving as joints to be joined to the electrically conductive pads 9₁ and 9₂ of the base member 5, are formed at the joint portion 13 on the other main surface side illustrated in FIG. 5.

As illustrated in FIG. 1, a plurality of electrodes pads 26; six electrode pads in the illustrated example, are formed on the lower surface of the second layer 5b constituting the substrate portion of the base member 5. These electrode pads are used for mounting of the IC4 and respectively correspond to six mounting terminals of the IC4. The IC4 is a bare chip IC embedded with an oscillator circuit. The IC4 is joined to the electrode pads 26 of the base member 5 with metal bumps 27, and parts of joint of the IC4 to these electrode pads 26 are filled with an underfill 28.

Two of the six electrode pads 26 of the base member 5 are connected, using an internal wiring not illustrated in the drawings, to the electrically conductive pads 9₁ and 9₂ to be mounted with the tuning fork crystal vibration piece 3. The other four electrodes pads 26 are respectively connected to four external terminals 29 at four corners of the lower end surface of the first layer 5a constituting the second frame portion of the base member 5. These four external electrodes 29 may be, for example, a power source terminal, a grand terminal, an output terminal, and an OE (Output enable) terminal.

Below is described the leakage of vibration energy which may be likely to occur with tuning fork-type vibration pieces of piezoelectric oscillators of the known art.

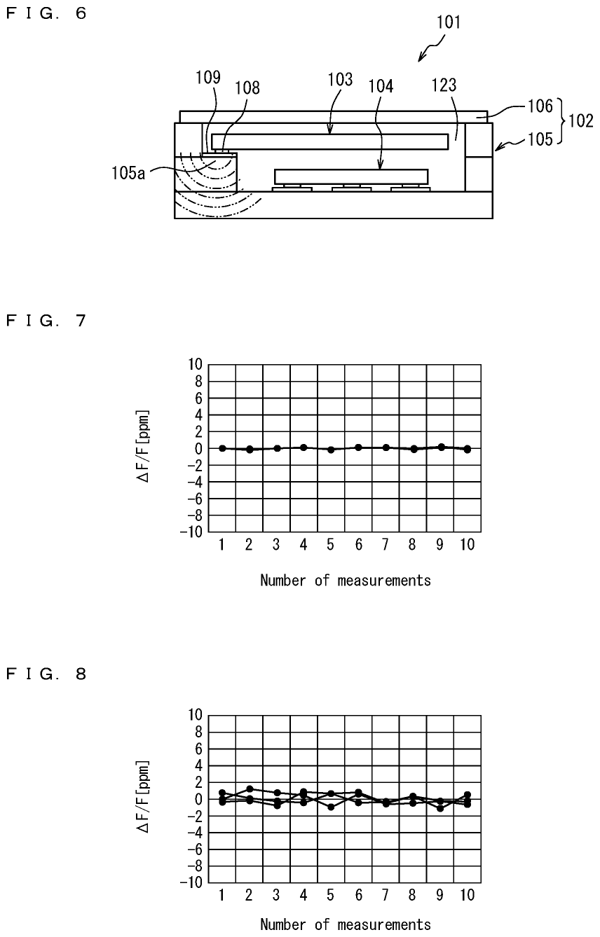

FIG. 6 is a schematic view in cross section of a crystal oscillator of the known art.

A crystal oscillator 101 illustrated in this drawing includes a cabinet 102 formed by a lid member 106 and a base member 105. The base member 105 has a housing recess 123 with an opening on its upper side. A tuning fork-type crystal vibration piece 103 and an IC104 are housed in the housing recess 123 of the base member 105, and the lid member 106 is bonded to an upper end of the base member 105 to hermetically seal the housing recess. This cabinet 102 has a single-package structure in which the tuning fork type crystal vibration piece 103 and the IC104 are housed together in the housing recess 123.

The housing recess 123 of the base member 5 includes a stepped portion 105a, and a metal bump 108 is disposed on the upper surface of this stepped portion. The tuning fork-type crystal vibration piece 103 is bonded, with the metal bump 108, to the electrically conductive pad 109.

In the crystal oscillator 101, vibration energy generated by the vibration arms of the tuning fork-type crystal vibration piece 103 is transmitted, through parts of joint of the electrically conductive pad 109 and the metal bump 108, to the base member 105 immediately below, as illustrated with virtual lines. This is how the leakage of vibration energy occurs.

The occurrence of this vibration energy leakage may destabilize the oscillation frequency of the crystal oscillator 101, leading to poor frequency reproducibility.

The crystal oscillator 101 may be mounted to an external circuit board. In this instance, stress, for example, bending stress, generated from the circuit board may be transmitted from the outer bottom surface of the cabinet 102 to parts of joint of the electrically conductive pad 109 and the metal bump 108. This may compromise a desired level of connection reliability between the tuning fork-type crystal vibration piece 103 and the base member 105.

The crystal oscillator 1 according to this embodiment is structured like an H-like package, as described earlier. While the electrically conductive pads 9₁ and 9₂ are formed on the mounting surface, and the tuning fork-type crystal vibration piece 3 is bonded to these pads using the metal bumps 8₁ and 8₂, a recess 30 is formed in the lower surface of the cabinet 2 on the opposite side of this mounting surface. To be specific, the recess 30 is formed by denting a center part of this lower surface toward the housing 23, except the rectangular first layer 5a constituting the second frame portion. A region except the outer periphery of the lower surface of the cabinet 2 includes a region that overlaps with the electrically conductive pads 9₁ and 9₂ in plan view. This recess 30, however, provides a space in this region to which no vibration may be transmittable to this region.

As illustrated with the virtual lines, vibration may possibly be transmitted from the arm portions 11 and 12 of the tuning fork-type crystal vibration piece 3 to the cabinet 2 through parts of joint of the electrically conductive pads 9₁ and 9₂ of the base member 5 and the metal bumps 8₁ and 8₂. The vibration, however, may be blocked by the space provided by the recess 30 in the region that overlaps with the electrically conductive pads 9₁ and 9₂ in plan view. This may prevent further spread of possible vibration energy leakage.

In the H-like package structure according to this embodiment, the third layer 5c of the base member 5 has, on its long sides of the rectangular shape in plan view (upper and lower sides on FIG. 2, right and left sides on FIG. 3), portions protruding slightly more inward than the fourth layer 5d. In plan view, therefore, the IC4-housing lower space with no inward protrusion may be larger than the upper space in which the tuning fork-type crystal vibration piece 3 is housed.

In case any vibration is conveyed from the paired arm portions 11 and 12 of the tuning fork-type crystal vibration piece 3 housed in the upper space, the lower space greater than the upper space may block such vibration, preventing further transmission of the vibration to the external terminals 29 formed on the lower first layer 5a of the base member 5. Thus, the risk of vibration energy leakage may be effectively reduced.

The external terminals 29 are formed on the lower surface of the first layer 5a of the base member 5, i.e., outer bottom surface of the cabinet 2. These external terminals 29 are formed in a region with no overlap with parts of joint of the electrically conductive pads 9₁ and 9₂ of the base member 5 and the metal bumps 8₁ and 8₂ in plan view. Thus, any vibration from the paired arm portions 11 and 12 of the tuning fork-type crystal vibration piece 3 may be prevented from transmitting to the external terminals 29 through the parts of joint. As a result, the risk of vibration energy leakage to outside of the cabinet 2 may be effectively reduced.

The IC4 is bonded, with the metal bumps 27, to the electrode pads 26 on the lower surface of the second layer 5b; substrate portion of the base member 5. This IC4 is mounted in a region with no overlap with parts of joint of the electrically conductive pads 9₁ and 9₂ of the base member 5 and the metal bumps 8₁ and 8₂ in plan view. Thus, any vibration from the paired arm portions 11 and 12 of the tuning fork-type crystal vibration piece 3 may be prevented from transmitting to the IC4 through the parts of joint. As a result, the risk of vibration energy leakage may be effectively reduced.

Any vibration of the tuning fork type crystal vibration piece 3 may be transmitted through parts of joint of the electrically conductive pads 9₁ and 9₂ of the base member 5 and the metal bumps 8₁ and 8₂. Supposing that a direction orthogonal to the upper surface of the second layer 5b; substrate portion, is the direction of thickness, regions of the external terminals 29, electrically conductive pads 9₁ and 9₂ and IC4 respectively have the following thicknesses.

The relationship of t1>t2>t3 is satisfied, where t1 is the thickness from the external terminal 29 to the upper surface of the third layer 5c where the electrically conductive pads 9₁ and 9₂ of the base member 5 are formed, t2 is the thickness of the region where the electrically conductive pads 9₁ and 9₂ of the base member 5 are formed, and t3 is the thickness of the IC4-mounted region.

Supposing that t1 is the thickness from the external terminal 29 to the upper surface of the third layer 5c, t2 is the thickness of the region where the electrically conductive pads 9₁ and 9₂ of the base member 5 are formed, and t3 is the thickness of the IC4-mounted region, the thicknesses t2, t2 and t3 differ from one another. These portions that differ in thickness may serve to attenuate any vibration from the tuning fork-type crystal vibration piece 3, reducing the risk of the vibration being transmitted to the external terminals 29 and the IC4.

The space is formed by the recess 30 immediately below the parts of joint of the electrically conductive pads 9₁ and 9₂ of the base member 5 and the metal bumps 8₁ and 8₂. In case the crystal oscillator 1 is mounted to an external circuit board, any stress, for example, bending stress from the circuit board may be released out through the space. This may successfully reduce the stress that possibly acts upon the parts of joint of the electrically conductive pads 9₁ and 9₂ and the metal bumps 8₁ and 8₂, leading to improved connection reliability between the turning fork type crystal vibration piece 3 and the base member 5.

FIG. 7 is a graph showing the result of measurement of frequency reproducibility in the crystal oscillator 1 according to this embodiment. In this graph, the lateral axis represents the number of measurements, and the vertical axis represents ΔF/F (ppm); ratio of a frequency shift ΔF relative to an average value F of measured frequency values.

FIG. 7 shows a frequency deviation in each of ten frequency measurements of N number of samples of the crystal oscillator 1; three samples in the illustrated example, based on the average value F of the ten frequency measurements.

In each measurement, the crystal oscillator 1 was inserted into an open-top socket made of a resin and then oscillated with a voltage being applied thereto from an external direct current power source. Then, the output of the crystal oscillator 1 was inputted to a frequency counter using a probe to conduct frequency measurement.

As illustrated in FIG. 7, three samples of the crystal oscillator 1 according to this embodiment hardly exhibited any frequency deviation, demonstrating good frequency reproducibility.

FIG. 8 is a graph showing the result of measurement of frequency reproducibility in the crystal oscillator 101 of the known art having a single-package structure of FIG. 6. This drawing is illustrated correspondingly to FIG. 7. The tuning fork type crystal vibration piece 103 and the IC104 of the crystal oscillator 101 are configured similarly to the tuning fork-type crystal vibration piece 3 and the IC104 of the crystal oscillator 4 of this embodiment.

Like FIG. 7, FIG. 8 shows a frequency deviation in each of ten frequency measurements of N number of samples of the crystal oscillator 101; three samples in the illustrated example, based on an average value F of the ten frequency measurements.

The crystal oscillator 101 of the known art illustrated in FIG. 6 is structured like a single package. This crystal oscillator, however, may fail to control the risk of vibration energy leakage well enough, unlike this embodiment. As illustrated in FIG. 8, the sample crystal oscillators 101 resulted in frequency shifts from the average value in each frequency measurement, thus demonstrating poor frequency reproducibility.

The measurement result of frequency reproducibility of the crystal oscillator 1 may be associated with an impact of vibration energy leakage generated after this oscillator is mounted to an external circuit board.

According to this embodiment, any vibration transmitted to the cabinet 2 through the parts of joint of the electrically conductive pads 9₁ and 9₂ of the base member 5 and the metal bumps 8₁ and 8₂ may be successfully blocked by the space provided by the recess 30 formed in the region that overlaps with the electrically conductive pads 9₁ and 9₂ in plan view. This may effectively control the risk of vibration energy leakage to the external terminals 29 and the IC4, conducing to oscillation frequency stability and favorable frequency reproducibility.

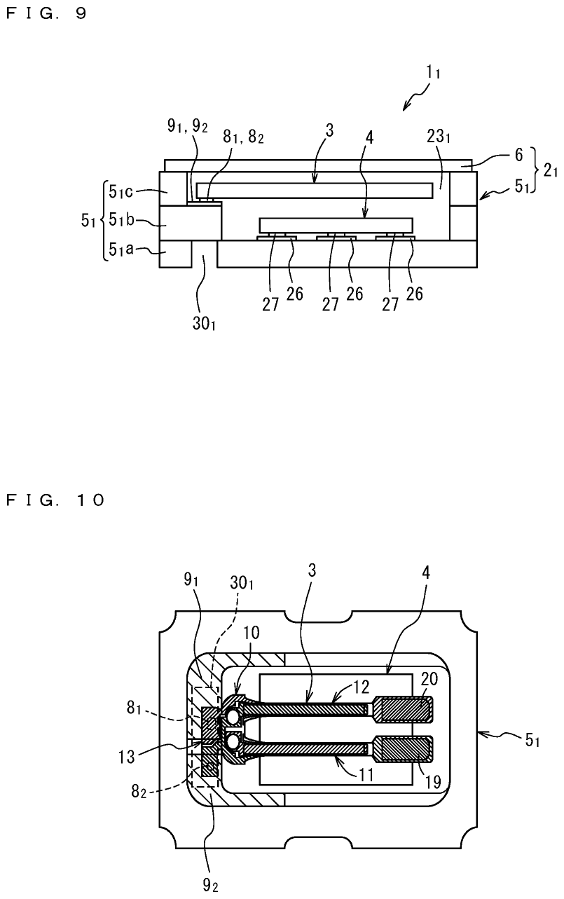

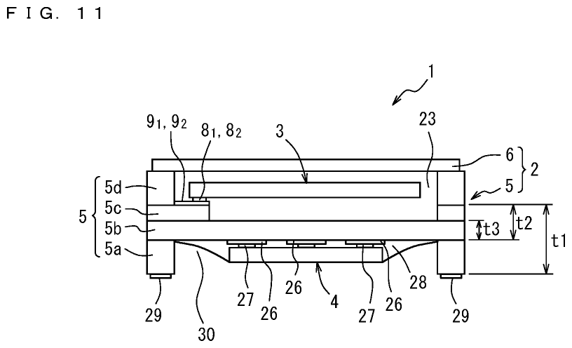

This embodiment described the H-like package structure in which the housing 23 of the tuning fork-type crystal vibration piece 3 is formed on the upper surface side of the second layer 5b serving as the substrate portion of the base member 5, and the recess 30 for housing of the IC4 is formed on the lower surface side of the second layer 5b. The technology disclosed herein may be applicable to a single package structure schematically illustrated in cross section in FIG. 9 and in plan view in FIG. 10.

In a crystal oscillator 1₁ according to this embodiment, a cabinet 2₁ includes a lid member 6 and a base member 5₁. The base member 5₁ has a recess with an opening on its upper side. The tuning fork type crystal vibration piece 3 and the IC4 are housed in a recess formed in the base member 5₁, and the lid member 6 is bonded to the upper end of the base member 5₁ to hermetically seal the recess. In the cabinet 1₂, the tuning fork-type crystal vibration piece 3 and the IC4 are housed together in a housing 231.

Ceramic green sheets are stacked in layers; specifically, a first layer 5₁a, a second layer 5₁b and a third layer 5₁c, and these layers are then fired into a unit to form the base member 5₁.

The first layer 5₁a constitutes a substrate portion rectangular in plan view. The second layer 5₁b and the third layer 5₁c on the first layer 5₁a form a rectangular frame portion on the upper surface of this substrate portion. Electrically conductive pads 9₁ and 9₂ for mounting of the tuning fork-type crystal vibration piece 3 are formed on the upper surface of a stepped portion protruding inward from one short side of the rectangular shape in plan view. The tuning fork-type crystal vibration piece 3 is bonded to these electrically conductive pads 9₁ and 9₂ using metal bumps 8₁ and 8₂.

A plurality of electrode pads 26 for mounting of the IC4 are formed on the upper surface of the first layer 5₁a, i.e., inner bottom surface of the base member 5. The IC4 is bonded to these electrode pads using metal bumps 27.

In this embodiment, a recess 301 is formed in the lower surface of the cabinet 2₁ on the opposite side of the mounting surface where the electrically conductive pads 9₁ and 9₂ are formed. To be specific, a center part of this lower surface is dented toward the housing 231. As illustrated in the plan view of FIG. 10, this recess 30₁ is formed in a rectangular region that overlaps with parts of joint of the electrically conductive pads 9₁ and 9₂ and the metal bumps 8₁ and 8₂ in plan view. The recess 30₁ may not necessarily be formed in this rectangular region but may be formed in any region that overlaps with parts of joint of the electrically conductive pads 9₁ and 9₂ and the metal bumps 8₁ and 8₂ in plan view. For example, this recess may be formed like a groove that extends along the whole length from one long side toward the other long side of the first layer 5₁a rectangular in plan view in a direction along short sides of the first layer 5₁a rectangular in plan view (vertical direction on FIG. 10) so as to include parts of joint of the electrically conductive pads 9₁ and 9₂ and the metal bumps 8₁ and 8₂ in plan view.

The recess 30₁ is thus formed in the rectangular region that overlaps with the parts of joint of the electrically conductive pads 9₁ and 9₂ and the metal bumps 8₁ and 8₂ in plan view. Thus, vibration, if transmitted to the cabinet 2₁ from the tuning fork-type crystal vibration piece 3 through the parts of joint of the electrically conductive pads 9₁ and 9₂ of the base member 5 and the metal bumps 8₁ and 8₂, may be successfully blocked by the space provided by the recess 30₁ formed in the region that overlaps with the electrically conductive pads 9₁ and 9₂ in plan view. This may effectively avoid further spread of the vibration energy leakage.

Any other technical advantages and effects are similar to those described in the earlier embodiment.

FIG. 11 is a schematic view in cross section according to an embodiment of this disclosure, illustrated correspondingly to FIG. 1. Any like components are illustrated with the same reference signs as in FIG. 1.

In this embodiment, an underfill 28 is used that covers parts of joint of the IC4 and the electrode pads 26 of the base member 5 using metal bumps 27. The underfill 28 is applied from the outer circumference of the IC4 to the inner peripheral edge of the first layer 5a of the base member 5.

The underfill 28 spreads so as to overlap in plan view with a region of joint of the tuning fork-type crystal vibration piece 3 with the electrically conductive pads 9₁ and 9₂ of the base member 5 using the metal bumps 8181 and 8₂.

The underfill 28 is made of a resin and is elastically deformable. The underfill 28, therefore, may effectively absorb vibration transmitted from parts of joint of the metal bumps 8 and the electrically conductive pads 9 of the base member 5 made of a hard ceramic material. Thus, the risk of vibration energy leakage may be successfully reduced.

Instead of forming the housing by bonding the flat lid member to the recess-formed base member, the package structure may have a housing formed by bonding a cap-like lid member to a flat base member.

The embodiments described thus far were applied to the oscillator; an example of the piezoelectric vibration device. These embodiments may be applied to any other suitable piezoelectric vibration devices, for example, piezoelectric vibrator or sensor-attached piezoelectric vibrator mounted with a temperature sensor, instead of the IC. The earlier embodiments were applied to the tuning fork-type crystal vibration piece that operates in a bending vibration mode. The technology disclosed herein may be applicable to, instead of tuning fork type devices, any other suitable crystal vibration devices using, for example, AT-cut crystal vibration pieces that operate in a thickness-shear vibration mode and may also be applied to any other piezoelectric materials but crystal.

### REFERENCE SIGNS LIST

1, 1₁, 101 crystal oscillator
2, 2₁, 102 cabinet
3, 103 tuning fork-type crystal vibration piece

1. A piezoelectric vibration device, comprising:
a piezoelectric vibration piece;
a cabinet with a housing in which the piezoelectric vibration piece is containable; and
an electrically conductive pad on a mounting surface of the housing to which the piezoelectric vibration device is mountable,
the piezoelectric vibration piece being bondable with a metal bump to the electrically conductive pad,
an outer surface of the cabinet on a side opposite to the mounting surface is recessed toward the mounting surface to form a space in a region that overlaps with the electrically conductive pad in plan view.

2. The piezoelectric vibration device according to claim 1, wherein the piezoelectric vibration piece is a piezoelectric vibration piece in the form of a tuning fork.

3. The piezoelectric vibration device according to claim 1 or 2, further comprising an external terminal on an outer bottom surface of the cabinet, wherein
the external terminal is formed in a region with no overlap with the electrically conductive pad in plan view.

4. The piezoelectric vibration device according to claim 3, wherein
the cabinet comprises a base member and a lid member,
the base member comprises the external terminal and the mounting surface on which the electrically conductive pad is formed, and
the lid member is bonded to the base member to seal the housing,
the base member further comprises:
a substrate portion;
a first frame portion; and
a second frame portion,
the first frame portion is formed in an annular manner in an outer periphery of one main surface of the substrate portion,
the second frame portion is formed in an annular manner in an outer periphery of another main surface of the substrate portion,
the lid member is bonded to an upper end surface of the first frame portion,
the housing is formed by the substrate portion, the first frame portion and the lid member form, and
the external terminal is formed on a lower end surface of the second frame portion.

5. The piezoelectric vibration device according to claim 4, wherein
a region defined by an inner peripheral edge of the second frame portion on the another main surface of the substrate portion of the base member has a greater dimension in plan view than a region defined by an inner peripheral edge of the first frame portion on the one main surface of the substrate portion.

6. The piezoelectric vibration device according to claim 4, wherein
the substrate portion and the second frame portion form a housing recess in which an integrated circuit element is containable,
the integrated circuit element is mounted to the another main surface of the substrate portion, and
a region mounted with the integrated circuit element does not overlap in plan view with a region of joint of the electrically conductive pad with the metal bump.

7. The piezoelectric vibration device according to claim 4, wherein
the substrate portion and the second frame portion form a housing recess in which an integrated circuit element is containable,
the integrated circuit element is mounted to the other main surface of the substrate portion, and
a region mounted with the integrated circuit element is filled with an underfill that spreads as far as a region of joint of the electrically conductive pad with the metal bump in plan view.

8. The piezoelectric vibration device according to claim 6, wherein
a stepped portion is formed on the one main surface of the substrate portion of the cabinet,
the electrically conductive pad is formed on an upper surface of the stepped portion to constitute the mounting surface, and
a first thickness is greater than a second thickness and the second thickness is greater than a third thickness, where the first thickness is a dimension from the mounting surface to the external terminal in a direction of thickness which is a direction orthogonal to the one main surface of the substrate portion of the cabinet, the second thickness is a dimension in the direction of thickness of a region where the electrically conductive pad is formed, and the third thickness is a dimension in the direction of thickness of the region mounted with the integrated circuit element.
